(19) United States
(12) Patent Application Publication
(10) Pub. No.: US 2026/0302070 A1
(43) Pub. Date: Oct. 1, 2026

(54) ELECTRONIC COMPONENT AND BOARD HAVING ELECTRONIC COMPONENT MOUNTED THEREON

(71) Applicant: SAMSUNG ELECTRO-MECHANICS CO., LTD., Suwon-si (KR)

(72) Inventors: Young Ghyu Ahn, Suwon-si (KR); Soo Hwan Son, Suwon-si (KR); Se Hun Park, Suwon-si (KR); Yeong Lim Kwon, Suwon-si (KR); Jeong Pil Jhun, Suwon-si (KR)

(73) Assignee: SAMSUNG ELECTRO-MECHANICS CO., LTD., Suwon-si (KR)

(21) Appl. No.: 19/543,511

(22) Filed: Feb. 18, 2026

(30) Foreign Application Priority Data
Mar. 28, 2025 (KR) 10-2025-0039948

(51) Int. Cl. H01G 4/232; H01G 4/30

(52) U.S. Cl. CPC H01G 4/2325; H01G 4/30

(57) ABSTRACT

An electronic component includes a capacitor including a body including a dielectric layer and an internal electrode, and an external electrode disposed on the body, a connection terminal disposed on the external electrode, and a bonding layer disposed between the capacitor and the connection terminal, the bonding layer including Au. The external electrode includes an electrode layer connected to the internal electrode, a Ni plating layer disposed on the electrode layer, and a Sn plating layer disposed on the Ni plating layer. When an average thickness of the bonding layer is defined as T1 and an average thickness of the Sn plating layer is defined as T2, T2>T1 is satisfied.

### CROSS-REFERENCE TO RELATED APPLICATION(S)

This application claims benefit of priority to Korean Patent Application No. 10-2025-0039948, filed on Mar. 28, 2025, in the Korean Intellectual Property Office, the disclosure of which is incorporated herein by reference in its entirety.

### TECHNICAL FIELD

The present disclosure relates to an electronic component and a board having an electronic mounted thereon.

A multilayer ceramic capacitor (MLCC) may be a chip-type condenser mounted on the printed circuit boards of various types of electronic products such as imaging devices, including a liquid crystal display (LCD) and a plasma display panel (PDP), computers, smartphones, mobile phones, and circuits such as on board charger (OBC) DC-DC converters of electric vehicles, and may serve to charge or discharge electricity therein or therefrom.

A dielectric layer included in the MLCC may have piezoelectricity and electrostriction. Accordingly, when a DC or AC voltage is applied to the MLCC, a piezoelectric phenomenon may occur between internal electrodes, causing vibrations.

Such vibrations may be transmitted through an external electrode of the MLCC to a printed circuit board on which the MLCC is mounted, resulting in a vibration sound. The vibration sound may correspond to an audible frequency within a range of 20 to 20,000 Hz causing discomfort to humans, and the vibration sound causing discomfort may be defined as acoustic noise.

In the related art, an attempt has been made to reduce acoustic noise by disposing a connection terminal on one surface of an external electrode of an MLCC.

However, the MLCC and the connection terminal may be separately formed and then bonded to each other. Thus, in a process of mounting an electronic component in which the MLCC and the connection terminal are coupled to each other on a substrate, misalignment caused by self-alignment may occur between the MLCC and the connection terminal, and adhesive strength may decrease due to insufficient bonding strength.

In an attempt to maximize acoustic noise reduction, a slit may be formed in the connection terminal to reduce the height of a solder fillet formed during mounting. When a slit is formed in the connection terminal, a printed circuit board and the connection terminal may have different forms. As a bonding area between the connection terminal and the external electrode of the capacitor decreases, the possibility of bonding misalignment defects and adhesive strength defects caused by insufficient bonding strength may increase.

Accordingly, there is a need for an improved bonding structure between an MLCC and a connection terminal capable of preventing bonding misalignment defects between the MLCC and the connection terminal and a reduction in adhesive strength caused by insufficient bonding strength between the MLCC and the connection terminal.

### SUMMARY

An aspect of the present disclosure is to alleviate bonding misalignment defects occurring between a capacitor and a connection terminal.

Another aspect of the present disclosure is to prevent a reduction in adhesive strength caused by insufficient bonding strength between a capacitor and a connection terminal.

However, the aspects of the present disclosure are not limited to those set forth herein, and will be more easily understood in the course of describing specific example embodiments of the present disclosure.

According to an aspect of the present disclosure, there is provided an electronic component including a capacitor including a body including a dielectric layer and an internal electrode, and an external electrode disposed on the body, a connection terminal disposed on the external electrode, and a bonding layer disposed between the capacitor and the connection terminal, the bonding layer including Au. The external electrode may include an electrode layer connected to the internal electrode, a Ni plating layer disposed on the electrode layer, and a Sn plating layer disposed on the Ni plating layer. When an average thickness of the bonding layer is defined as T1 and an average thickness of the Sn plating layer is defined as T2, T2>T1 may be satisfied.

According to an example embodiment of the present disclosure, a bonding layer including Au may be disposed between a capacitor and a connection terminal, thereby alleviating bonding misalignment defects between the capacitor and the connection terminal.

According to an example embodiment of the present disclosure, a bonding layer including Au may be disposed between a capacitor and a connection terminal, thereby preventing a reduction in adhesive strength between the capacitor and the connection terminal caused by insufficient bonding strength.

However, the various advantages and effects of the present disclosure are not limited to those set forth herein, and will be more easily understood in the course of describing specific example embodiments of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic perspective view of an electronic component according to an example embodiment of the present disclosure;

FIG. 2 is a schematic perspective view of an electronic component according to an example embodiment of the present disclosure, excluding a connecting electrode portion;

FIG. 3 is a schematic cross-sectional view taken along line I-I′ in FIG. 1;

FIG. 4 is a schematic cross-sectional view taken along line II-II′ in FIG. 1;

FIG. 5 is a schematic enlarged view of region “P” in FIG. 3;

FIG. 6 is a schematic cross-sectional view of an electronic component according to an example embodiment of the present disclosure mounted on a board;

FIG. 7 is a schematic perspective view of an electronic component according to another example embodiment of the present disclosure; and

FIG. 8 is a schematic cross-sectional view taken along line III-III′ in FIG. 7.

### DETAILED DESCRIPTION

Hereinafter, example embodiments of the present disclosure are described with reference to the accompanying drawings. The present disclosure may, however, be exemplified in many different forms and should not be construed as being limited to the specific example embodiments set forth herein. In addition, example embodiments of the present disclosure may be provided for a more complete description of the present disclosure to those skilled in the art. Accordingly, the shapes and sizes of the elements in the drawings may be exaggerated for clarity of description, and elements denoted by the same reference numerals in the drawings may be the same elements.

In order to clearly illustrate the present disclosure, portions not related to the description are omitted, and sizes and thicknesses are magnified in order to clearly represent layers and regions, and similar portions having the same functions within the same scope are denoted by similar reference numerals throughout the specification. Throughout the specification, when an element is defined as “comprising” or “including,” it means that it may include other elements as well, rather than excluding other elements, unless specifically stated otherwise.

In the drawings, an X-direction may be a thickness direction, a Y-direction may be a length direction, and a Z-direction may be a width direction, and a lamination direction (e.g., stacking direction) of internal electrodes 121 and 122 or a dielectric layer 111 may be a thickness direction or a width direction.

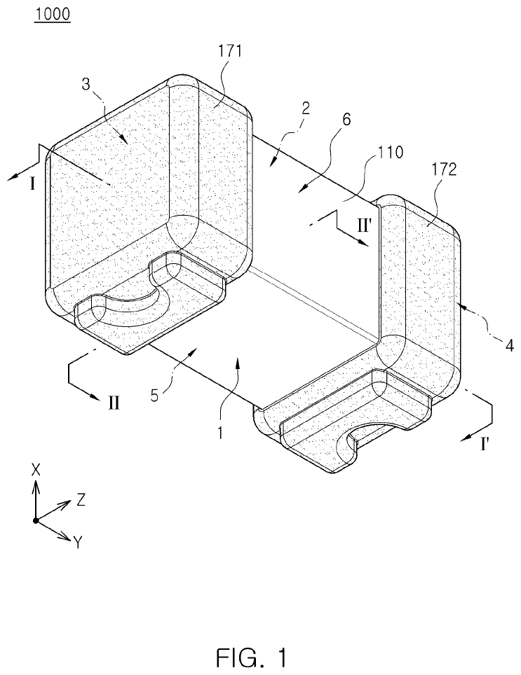

FIG. 1 is a schematic perspective view of an electronic component according to an example embodiment of the present disclosure.

Referring to FIG. 1, an electronic component 1000 may include a body 110 and conductive portions 171 and 172 disposed on the body 110. The conductive portions 171 and 172 may be regions including external electrodes 131 and 132, connection terminals 141 and 142, and bonding layers 161 and 162 to be described below. In some cases, the conductive portions 171 and 172 may be regions including connection electrode portions 151 and 152 disposed on the external electrodes 131 and 132 and the connection terminals 141 and 142.

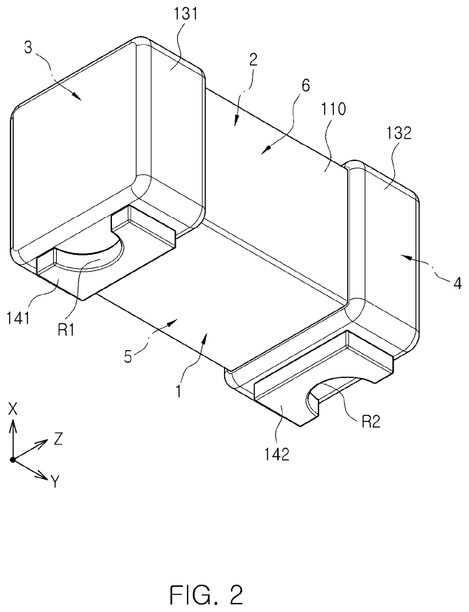

FIG. 2 is a schematic perspective view of an electronic component according to an example embodiment of the present disclosure, excluding a connecting electrode portion.

Referring to FIGS. 1 and 2, the electronic component 1000 may include a capacitor 100 including a body 110 and external electrodes 131 and 132 disposed on the body 110, and connection terminals 141 and 142 disposed on the external electrodes 131 and 132.

A specific shape of the body 110 is not limited. However, as illustrated in FIG. 2, the body 110 may have a hexahedral shape or a shape similar thereto. During a sintering process, ceramic powder particles included in the body 110 may shrink, such that the body 110 may not have a hexahedral shape having perfectly straight lines, but may have a substantially hexahedral shape.

The body 110 may have first and second surfaces 1 and 2 opposing each other in the first direction (e.g., X-direction), third and fourth surfaces 3 and 4 connected to the first and second surfaces 1 and 2, the third and fourth surfaces 3 and 4 opposing each other in a second direction (e.g., Y-direction), perpendicular to the first direction, and fifth and sixth surfaces 5 and 6 connected to the first and second surfaces 1 and 2 and connected to third and fourth surfaces 3 and 4, the fifth and sixth surfaces 5 and 6 opposing each other in a third direction (e.g., Z-direction), perpendicular to the first and second directions.

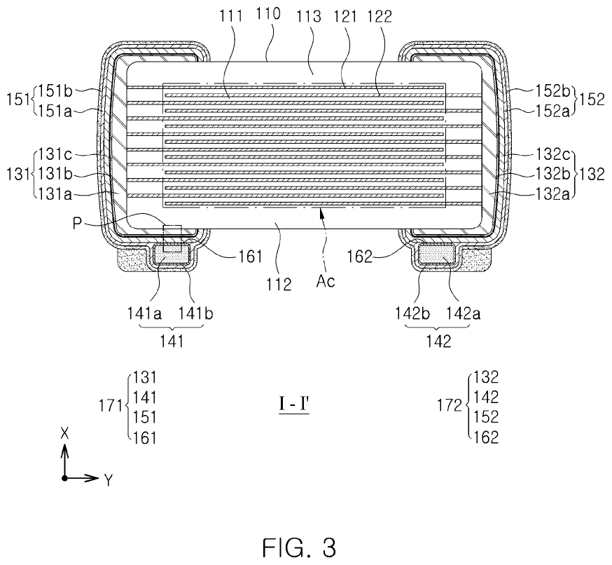

FIG. 3 is a schematic cross-sectional view taken along line I-I′ in FIG. 1.

Referring to FIG. 3, the body 110 may include a dielectric layer 111 and internal electrodes 121 and 122.

The dielectric layer 111 and the internal electrodes 121 and 122 may be alternately disposed in the first direction. That is, in the present disclosure, the first direction may refer to a lamination direction of the dielectric layer 111 and the internal electrodes 121 and 122.

The dielectric layer 111 may be in a sintered state, and adjacent dielectric layers 111 may be integrated with each other such that boundaries therebetween are not readily apparent without using a scanning electron microscope (SEM). The number of laminated dielectric layers is not limited, and may be determined in consideration of a size of the electronic component. For example, the body may be formed by laminating 400 or more dielectric layers.

The dielectric layer 111 may be formed by preparing a ceramic slurry including ceramic powder particles, an organic solvent, and a binder, coating the slurry on a carrier film and drying the same to prepare a ceramic green sheet, and then sintering the ceramic green sheet. The ceramic powder particles are not limited as long as sufficient capacitance is obtainable therewith, and may be, for example, barium titanate-based ((BaTiO₃)-based) powder particles and CaZrO₃-based paraelectric powder particles. As a more specific example, the barium titanate-based ((BaTiO₃)-based) powder particles may be one or more of BaTiO₃, (Ba₁₋ₓCaₓ)TiO₃ (0<x<1), Ba(Ti_{1-y}Ca_{y})O₃ (0<y<1), (Ba₁₋ₓCaₓ)(Ti_{1-y}Zr_{y})O₃ (0<x<1, 0<y<1), and Ba(Ti_{1-y}Zr_{y})O₃ (0<y<1), and CaZrO₃-based paraelectric powder particles may be (Ca₁₋ₓSrₓ)(Zr_{1-y}Ti_{y})O₃ (0<x<1, 0<y<1).

A thickness (td) of the dielectric layer 111 is not limited.

For example, in order to more easily achieve high capacitance and miniaturization of the electronic component 1000, the average thickness (td) of the dielectric layer 111 may be 0.35 μm or less. In order to improve reliability of the electronic component 1000 under high-temperature and high-pressure conditions, the average thickness (td) of the dielectric layer 111 may be 1 μm or more.

The average thickness (td) of the dielectric layer 111 is not limited. For example, in order to more easily achieve high capacitance and miniaturization of the electronic component 1000, the average thickness (td) of the dielectric layer 111 may be 0.35 μm or less. In order to improve reliability of the electronic component 1000 under high-temperature and high-pressure conditions, the average thickness (td) of the dielectric layer 111 may be 1 μm or more.

The average thickness (td) of the dielectric layer 111 may refer to an average thickness in the first direction of one or more first dielectric layers, among a plurality of first dielectric layers.

The average thickness in the first direction of the dielectric layer 111 may be measured by scanning, using an SEM, an image of a cross-section in the first and second directions of the electronic component 1000 at a magnification of 10,000×. More specifically, an average thickness in the first direction of a single dielectric layer 111 may refer to an average value of thicknesses of the single dielectric layer 111, measured at four points spaced apart from each other at equal intervals in the second direction, in the scanned image. The four points, spaced apart from each other at equal intervals, may be designated in a capacitance formation portion Ac. In addition, when such average value measurement is performed on four dielectric layers 111, the average thickness in the first direction of the dielectric layer 111 may be further generalized.

The body 110 may include a capacitance formation portion Ac disposed in the body 110, the capacitance formation portion Ac having capacitance by including a first internal electrode 121 and a second internal electrode 122 alternately disposed with the dielectric layer 111, and cover portions 112 and 113 disposed on upper and lower portions in the first direction of the capacitance formation portion Ac.

The capacitance formation portion Ac may be a portion contributing to formation of capacitance of a capacitor 100, and may be formed by repeatedly laminating a plurality of first and second internal electrodes 121 and 122 with the dielectric layer 111 interposed therebetween, and may refer to a region in which the first and second internal electrodes 121 and 122 overlap each other in the first direction. In addition, the first internal electrode 121 may be disposed on an uppermost end in the first direction of the capacitance formation portion Ac, and the second internal electrode 122 may be disposed on a lowermost end in the first direction of the capacitance formation portion Ac.

The internal electrodes 121 and 122 may include first and second internal electrodes 121 and 122. The first and second internal electrodes 121 and 122 may be alternately disposed to oppose each other with the dielectric layer 111 included in the body 110 interposed therebetween, and may be exposed to the third and fourth surfaces 3 and 4, respectively, of the body 110. That is, in an example embodiment, one end in the second direction of the first internal electrode 121 may be in contact with the third surface 3, and one end in the second direction of the second internal electrode 122 may be in contact with the fourth surface 4.

The first internal electrode 121 may be connected to a first external electrode 131, and the second internal electrode 122 may be connected to a second external electrode 132.

The first internal electrode 121 may not be connected to the second external electrode 132 but may be connected to the first external electrode 131, and the second internal electrode 122 may not be connected to the first external electrode 131 but may be connected to the second external electrode 132. That is, the first internal electrode 121 may be formed to be spaced apart from the fourth surface 4 by a predetermined distance, and the second internal electrode 122 may be formed to be spaced apart from the third surface 3 by a predetermined distance. In addition, the first and second internal electrodes 121 and 122 may be disposed to be spaced apart from fifth and sixth surfaces of the body 110.

A conductive metal, included in the internal electrodes 121 and 122, may include one or more of Ni, Cu, Pd, Ag, Au, Pt, In, Sn, Al, Ti, and alloys thereof, but the present disclosure is not limited thereto.

A thickness (the) of each of the internal electrodes 121 and 122 is not limited.

In order to more easily achieve high capacitance and miniaturization of the electronic component 1000, the average thickness (the) of each of the internal electrodes 121 and 122 may be 0.35 μm or less. In order to improve reliability of the electronic component 1000 under high-temperature and high-pressure conditions, the average thickness (the) of each of the internal electrodes 121 and 122 may be 1 μm or more.

The average thickness (the) of each of the internal electrodes 121 and 122 may refer to an average thickness in the first direction of one or more internal electrodes 121 and 122, among a plurality of internal electrodes 121 and 122.

The average thickness in the first direction of each of the internal electrodes 121 and 122 may be measured by scanning, using an SEM, an image of a cross-section in the first and second directions of the electronic component 1000 at a magnification of 10,000×. More specifically, an average thickness in the first direction of a single internal electrode may refer to an average value of thicknesses of the single internal electrode, measured at four points spaced apart from each other at equal intervals in the second direction, in the scanned image. The four points, spaced apart from each other at equal intervals, may be designated in the capacitance formation portion Ac. In addition, when such average value measurement is performed on four internal electrodes 121 and 122, the average thickness in the first direction of each of the internal electrodes 121 and 122 may be further generalized.

Referring to FIG. 3, the external electrodes 131 and 132 may be disposed on the body 110, and more specifically, may be disposed on the third surface 3 and the fourth surface 4 of the body 110.

The external electrodes 131 and 132 may include the first external electrode 131 disposed on the third surface 3 of the body 110, and the second external electrode 132 disposed on the fourth surface 4 of the body 110.

The external electrodes 131 and 132 may include electrode layers 131a and 132a disposed on the body 110, the electrode layers 131a and 132a connected to the internal electrodes 121 and 122.

The electrode layers 131a and 132a may be connected to the internal electrodes 121 and 122, respectively, and thus may serve to secure electrical connectivity between the external electrodes 131 and 132 and the internal electrodes 121 and 122.

The electrode layers 131a and 132a may include a conductive metal. A material having excellent electrical conductivity may be used as the conductive metal, and the material is not limited. For example, the conductive metal may be one or more of nickel (Ni), copper (Cu), and alloys thereof, and the electrode layers 131a and 132a may include Cu in order to secure electrical conductivity and coupling force through alloy formation with the Ni internal electrodes.

As a more specific example of the electrode layers 131a and 132a, the electrode layer may be a sintered electrode including a conductive metal and glass, or a resin-based electrode including a conductive metal and a resin.

The electrode layers 131a and 132a may be formed in a structure in which a sintered electrode and a resin-based electrode are sequentially formed on the body. In addition, the electrode layer may be formed by transferring a sheet including a conductive metal onto the body, or by transferring a sheet including a conductive metal onto a sintered electrode.

Plating layers 131b, 132b, 131c, and 132c may be disposed on the electrode layers 131a and 132a.

The plating layers 131b, 132b, 131c, and 132c may serve to improve sealing properties or mounting properties of the electronic component 1000.

As a more specific example of the plating layers 131b, 132b, 131c, and 132c, the plating layers 131b, 132b, 131c, and 132c may include Ni plating layers 131b and 132b including Ni, and Sn plating layers 131c and 132c disposed on the Ni plating layers 131b and 132b, the Sn plating layers 131c and 132c including Sn.

Referring to FIG. 3, the connection terminals 141 and 142 may be disposed on the external electrodes 131 and 132. More specifically, the connection terminals 141 and 142 may be disposed on one of upper and lower surfaces in the first direction of the external electrodes 131 and 132.

The connection terminals 141 and 142 may connect the capacitor 100 to a printed circuit board to be described below, and may serve to reduce acoustic noise of the electronic component by absorbing vibrations generated in the capacitor 100.

When the connection terminals 141 and 142 are formed of an insulating material, the connection terminals 141 and 142 may have land patterns functioning as signal terminals and ground (GND) terminals on upper and lower surfaces thereof.

When the connection terminals 141 and 142 are formed of a conductive material, an electrical connection may be achieved through all surfaces.

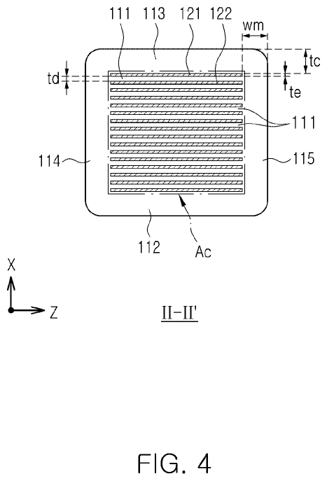

FIG. 4 is a schematic cross-sectional view taken along line II-II′ in FIG. 1.

Referring to FIG. 4, cover portions 112 and 113 may be disposed on upper and lower surfaces in the first direction of the capacitance formation portion Ac.

The cover portions 112 and 113 may basically serve to prevent the internal electrode from being damaged due to physical or chemical stress.

The cover portions 112 and 113 may include a material the same as that of the dielectric layer 111. That is, the cover portions 112 and 113 may include a ceramic material, for example, a barium titanate ((BaTiO₃)-based) ceramic material.

A thickness of each of the cover portions 112 and 113 is not limited. For example, the thickness of each of the cover portions 112 and 113 may be 20 μm or less.

An average thickness of each of the cover portions 112 and 113 may refer to a size in the first direction, and may be an average value of sizes in the first direction of each of the cover portions 112 and 113 measured at five points, spaced apart from each other at equal intervals, in an upper or lower portion of the capacitance formation portion Ac.

Referring to FIG. 4, margin portions 114 and 115 may be disposed on side surfaces of the capacitance formation portion Ac.

The margin portions 114 and 115 may include a first margin portion 114 disposed on the fifth surface 5 of the body 110, and a second margin portion 115 disposed on the sixth surface 6 of the body 110. That is, the margin portions 114 and 115 may be disposed on both end surfaces in the width direction of the body 110, respectively.

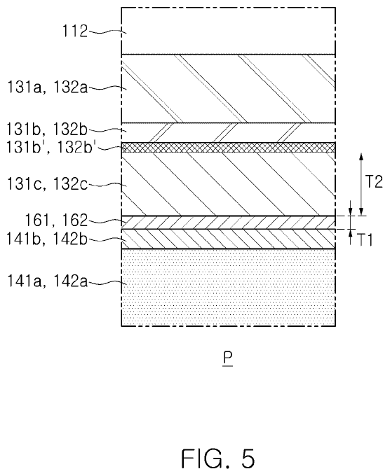

As illustrated in FIG. 5, the margin portions 114 and 115 may refer to regions between both ends of each of the first and second internal electrodes 121 and 122 and a boundary surface of the body 110 in a cross-section of the body 110 cut in a width-thickness (W-T) direction.

The margin portions 114 and 115 may basically serve to prevent the internal electrode from being damaged due to physical or chemical stress.

The margin portions 114 and 115 may be formed by forming an internal electrode by coating a conductive paste on a ceramic green sheet, except for a portion of the ceramic green sheet on which a margin portion is to be formed.

A width of each of the margin portions 114 and 115 is not limited. For example, an average width of each of the margin portions 114 and 115 may be 20 μm or less.

The average width of each of the margin portions 114 and 115 may refer to an average size in the third direction of a region in which the internal electrode is spaced apart from the fifth surface and an average size in the third direction of a region in which the internal electrode is spaced apart from the sixth surface, and may be an average value of the sizes in the third direction of the margin portions 114 and 115 measured at five points, spaced apart from each other at equal intervals, in the side surfaces of the capacitance formation portion Ac.

FIG. 5 is a schematic enlarged view of region “P” in FIG. 3.

In the related art, an attempt has been made to reduce acoustic noise by disposing connection terminals 141 and 142 on one surface of external electrodes 131 and 132 of a capacitor 100.

However, the capacitor 100 and the connection terminals 141 and 142 may be separately manufactured and then bonded to each other, misalignment may occur between the capacitor 100 and the connection terminals 141 and 142 due to a self-alignment phenomenon in a process of mounting an electronic component 1000 on a printed circuit board. In addition, when bonding strength is insufficient, adhesive strength may decrease.

Accordingly, in an example embodiment of the present disclosure, bonding layers 161 and 162 including Au may be disposed between the capacitor 100 and the connection terminals 141 and 142, the electronic component 1000 may alleviate or prevent bonding misalignment defects between the capacitor and the connection terminals and a reduction in adhesive strength caused by insufficient bonding strength between the capacitor and the connection terminals.

Specifically, referring to FIG. 5, in an example embodiment of the present disclosure, the external electrodes 131 and 132 may include electrode layers 131a and 132a electrically connected to the internal electrodes, Ni plating layers 131b and 132b disposed on the electrode layers 131a and 132a, and Sn plating layers 131c and 132c disposed on the Ni plating layers 131b and 132b. The bonding layers 161 and 162 including Au may be disposed between the capacitor 100 and the connection terminals 141 and 142, thereby forming a robust Au—Sn metallic bond between the Sn plating layers 131c and 132c and the bonding layers 161 and 162. Accordingly, the effect of alleviating bonding misalignment defects and a reduction in adhesive strength due to insufficient bonding between the capacitor and the connection terminals of the electronic component 1000 may be achieved.

A correlation between an average thickness (T1) of each of the bonding layers 161 and 162 and an average thickness (T2) of each of the Sn plating layers 131c and 132c may be appropriately adjusted to improve adhesive strength and alleviate bonding misalignment defects. Specifically, in an example embodiment of the present disclosure, T2>T1 may be satisfied, thereby further improving adhesive strength of the electronic component 1000 and alleviating bonding misalignment defects of the electronic component 1000.

When T2/T1 is greater than 1000, a proportion of Sn in coupling between the Sn plating layers 131c and 132c and the bonding layers 161 and 162 may be excessive, and Au may not sufficiently contribute to coupling, which may cause bonding misalignment defects. Accordingly, in an example embodiment, T2/T1 may be greater than 1 and less than 1000, thereby maintaining the effect of alleviating bonding misalignment defects and suppressing the occurrence of bonding misalignment defects.

In an example embodiment, the average thickness (T1) of each of the bonding layers 161 and 162 and the average thickness (T2) of each of the Sn plating layers 131c and 132c may be measured in regions in which the external electrodes 131 and 132 and the connection terminals 141 and 142 are connected to each other, in a cross-section in the first and second directions obtained by polishing the electronic component 1000 up to a halfway point in the second direction.

Specifically, components of each layer may be observed and analyzed in an EDS mode of an SEM, a transmission electron microscope (TEM), or a scanning transmission electron microscope (STEM), an average thickness of a region in which Au is present may be measured as the average thickness (T1) of each of the bonding layer 161 and 162, and a region having an Sn content of 90 at % or higher may be measured as the average thickness (T2) of the Sn plating layer. The average thickness (T1) of each of the bonding layer 161 and 162 and the average thickness (T2) of the Sn plating layer may refer to average values of thicknesses in the first direction measured at three or more points spaced apart from each other at equal intervals. Other methods and/or tools appreciated by one of ordinary skill in the art, even if not described in the present disclosure, may also be used.

The type of Au—Sn metallic coupling between the Sn plating layers 131c and 132c and the bonding layers 161 and 162 is not limited. However, Sn of the Sn plating layers 131c and 132c and Au of the bonding layers 161 and 162 may diffuse into each other to form an intermetallic compound including Au and Sn. That is, in an example embodiment, the bonding layers 161 and 162 may include an intermetallic compound including Au and Sn.

The intermetallic compound including Au and Sn may be stable and may have high mechanical strength, thereby improving adhesive strength between the capacitor 100 and the connection terminals 141 and 142 in the electronic component 1000 and suppressing bonding misalignment defects.

Examples of the intermetallic compound including Au and Sn may include AuSn, AusSn, AuSn₂, and AuSn₄, and the bonding layers 161 and 162 according to an example embodiment may include one or more of AuSn, AusSn, AuSn₂, and AuSn₄.

In an example embodiment, the bonding layers 161 and 162 may be regions in direct contact with the Sn plating layers 131c and 132c of the external electrodes 131 and 132, such that the bonding layers 161 and 162 may not include glass or resin. Specifically, the bonding layers 161 and 162 may be plating layers substantially including no glass or resin. The bonding layers 161 and 162 substantially including no glass or resin may mean that a ratio of content of metal elements to total elements of the bonding layers 161 and 162 is 90 at % or higher, but the present disclosure is not limited thereto.

Referring to FIG. 3, in an example embodiment, the connection terminals 141 and 142 may be disposed between both ends in the second direction of the external electrodes 131 and 132. More specifically, the connection terminals 141 and 142 may be disposed not to extend beyond one end and the other end in the second direction of the external electrodes 131 and 132, thereby enabling high-density and high-integration mounting of the electronic component 1000.

Referring to FIGS. 1 and 3, the electronic component 1000 according to an example embodiment may further include connection electrode portions 151 and 152 connecting the external electrodes 131 and 132 and the connection terminals 141 and 142 to each other. The connection electrode portions 151 and 152 may serve to more firmly couple the external electrodes 131 and 132 of the capacitor 100 to the connection terminals 141 and 142.

Referring to FIG. 3, the connection electrode portions 151 and 152 may cover outermost surfaces of the external electrodes 131 and 132 and outermost surfaces of the connection terminals 141 and 142. That is, the connection electrode portions 151 and 152 may be outermost layers of the conductive portions 171 and 172 of the present disclosure.

The connection electrode portions 151 and 152 may have a single-layer structure although not illustrated, or may have a multilayer structure as illustrated in FIG. 3. When the connection electrode portions 151 and 152 have a single-layer structure, the connection electrode portions 151 and 152 may be Sn plating portions. When the connection electrode portions 151 and 152 have a multilayer structure, the connection electrode portions 151 and 152 may have a structure in which Ni plating portions 151a and 152a and Sn plating portions 151b and 152b are sequentially disposed.

The plating portions 151a, 152a, 151b, and 152b, included in the connection electrode portions 151 and 152, are referred to as “plating portions” to distinguish the plating portions from plating layers 131b, 131c, 132b, and 132c of the external electrodes 131 and 132. However, the plating portions may have a composition substantially the same as that of the plating layers 131b, 131c, 132b, and 132c.

When the connection terminals 141 and 142 are formed of a conductive material, the connection terminals 141 and 142 may include terminal main bodies 141a and 142a and terminal layers 141b and 142b disposed on the terminal main bodies 141a and 142a. In this case, the terminal main bodies 141a and 142a may serve to further reduce acoustic noise, and the terminal layers 141b and 142b may serve to further improve coupling strength with bonding layers 161 and 162 or to relieve stress caused by interlayer coupling between the connection terminals 141 and 142 and the external electrodes 131 and 132.

Specifically, the terminal main bodies 141a and 142a may include Cu to more effectively reduce acoustic noise, and the terminal layers 141b and 142b may be formed as Ni plating layers including Ni, thereby further improving coupling strength with the bonding layers 161 and 162 or relieving stress caused by interlayer coupling between the connection terminals 141 and 142 and the external electrodes 131 and 132.

Referring to FIG. 2, the connection terminals 141 and 142 may include recessed grooves (e.g., concave grooves) R1 and R2 recessed inwardly in the second direction from ends thereof in the second direction. The grooves R1 and R2 may serve as solder pockets retaining solders 221 and 222 used when the electronic component 1000 according to an example embodiment is mounted on a substrate 200. Accordingly, the electronic component 1000 according to an example embodiment may reduce acoustic noise by suppressing transmission of vibrations of the capacitor 100 to the substrate 200.

When the connection terminals 141 and 142 include the grooves R1 and R2 recessed inwardly in the second direction from the ends in the second direction, a shape of the substrate 200 and a shape of each of the electrode pads 211 and 212 may be different from each other. Thus, bonding misalignment and a reduction in adhesive strength between the electronic component 1000 and the substrate 200 may occur.

However, in an example embodiment of the present disclosure, the bonding layers 161 and 162 including Au may be disposed between the capacitor 100 and the connection terminals 141 and 142, such that strong adhesion may be formed between the capacitor 100 and the connection terminals 141 and 142, thereby suppressing bonding misalignment between the electronic component 1000 and the substrate 200. As a result, a reduction in adhesive strength may also be alleviated.

Referring to FIG. 2, a shape of each of the grooves R1 and R2 may be a curved shape. More specifically, a length in the second direction of each of the connection terminals 141 and 142 may decrease toward a central portion in the third direction of each of the connection terminals 141 and 142. Accordingly, manufacturability of the connection terminals 141 and 142 may be improved. However, the shape of each of the grooves R1 and R2 is not limited to the curved shape, and the shape of each of the grooves R1 and R2 may be changed in various manners.

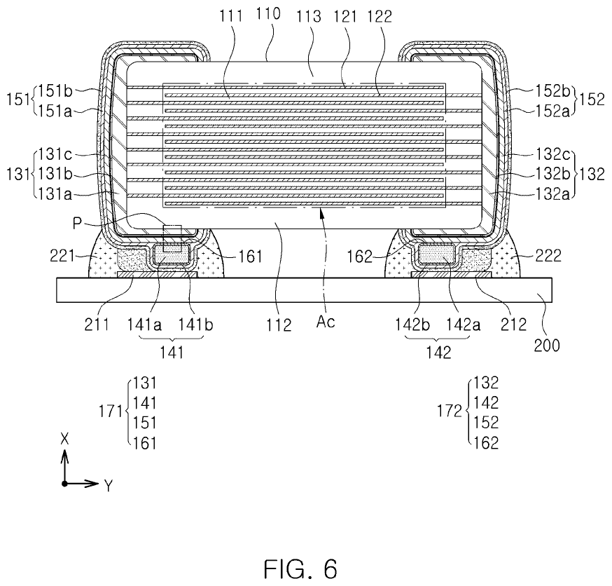

FIG. 6 is a schematic cross-sectional view of an electronic component according to an example embodiment of the present disclosure mounted on a board.

Referring to FIG. 6, the electronic component 1000 according to an example embodiment of the present disclosure and an electronic component 1000 according to various example embodiments thereof may be mounted on a substrate 200. Specifically, electrode pads 211 and 212 may be disposed on the substrate 200, and the electronic component 1000 may be disposed on the electrode pads 211 and 212. The electrode pads 211 and 212 may be in direct contact with conductive portions 171 and 172 of the electronic component 1000, and solders 221 and 222 may be disposed between the electrode pads and the conductive portions 171 and 172.

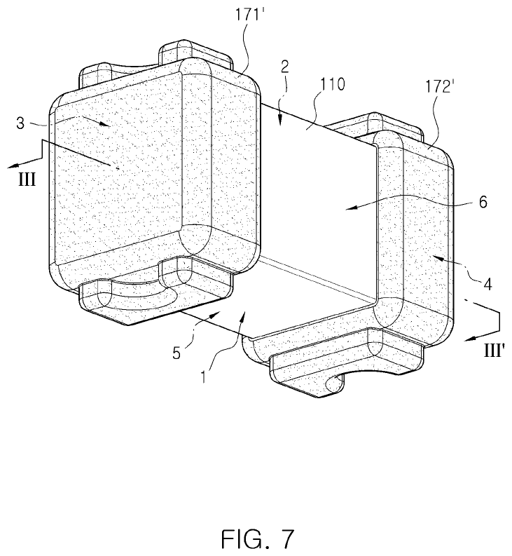

FIG. 7 is a schematic perspective view of an electronic component according to another example embodiment of the present disclosure.

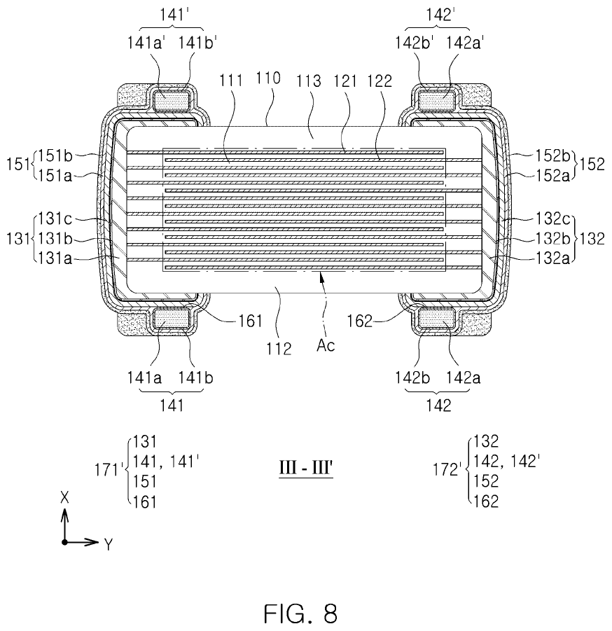

FIG. 8 is a schematic cross-sectional view taken along line III-III′ in FIG. 7.

Referring to FIGS. 7 and 8, an electronic component 1000′ according to another example embodiment of the present disclosure may include conductive portions 171′ and 172′ disposed on a body 110.

The conductive portions 171′ and 172′ may include a capacitor 100 including a body 110 and external electrodes 131 and 132, substantially the same as those of the electronic component 1000 according to an example embodiment of the present disclosure.

Conversely, the electronic component 1000′ according to another example embodiment of the present disclosure may include lower connection terminals 141 and 142 and upper connection terminals 141′ and 142′, disposed on an upper surface and a lower surface in a first direction of the capacitor 100.

Characteristics of the lower connection terminals 141 and 142 and the upper connection terminals 141′ and 142′ may be substantially the same as those of the connection terminals 141 and 142 of the electronic component 1000 according to an example embodiment of the present disclosure. Specifically, the upper connection terminals 141′ and 142′ may include a terminal main body 141a′ including Cu, and a terminal layer 141b′ including Ni, the terminal layer 141b′ disposed on the terminal main body 141a′.

### Experimental Example

Table 1 shows results of evaluating the influence of a relationship (T2/T1) between an average thickness (T1) of a bonding layer including Au according to an example embodiment of the present disclosure and an average thickness (T2) of an Sn plating layer on adhesive strength and bonding alignment.

The adhesive strength was evaluated using a die shear tester (Dage 4000+) product. Each sample was mounted on a PCB substrate, and the maximum force (N) applied until the product was detached was measured using a measurement tip. The number of samples was 10 for each test number. When there was a sample having a measured value not greater than a reference value, the sample was treated as NG. In Table 1, an experiment was conducted using a sample having a size of 1005, and a sample having adhesive strength, not exceeding 5N, was treated as NG.

The misalignment evaluation was evaluated using an automatic optical inspection (AOI) facility. When there was a sample deviating by ±75 μm or more from a position in which the sample is designated, the sample was treated as NG. An experiment was conducted on 10 samples for each test number, and a sample size corresponded to a size of 1005.

TABLE 1

| | | | | Adhesive | Bonding |
|---|---|---|---|---|---|
| Test | | | | strength | misalignment |
| No. | T2/T1 | T2 (μm) | T1(μm) | evaluation | evaluation |
| 1 | 1900 | 9.5 | 0.005 | OK | NG |
| 2 | 1000 | 10 | 0.01 | OK | OK |
| 3 | 550 | 11 | 0.02 | OK | OK |
| 4 | 200 | 10 | 0.05 | OK | OK |
| 5 | 120 | 12 | 0.1 | OK | OK |
| 6 | 55 | 11 | 0.2 | OK | OK |
| 7 | 20 | 10 | 0.5 | OK | OK |
| 8 | 10 | 5 | 0.5 | OK | OK |
| 9 | 2 | 1 | 0.5 | OK | OK |
| 10 | 1 | 0.5 | 0.5 | NG | OK |
| 11 | 0.2 | 0.1 | 0.5 | NG | OK |

Referring to Table 1, for test numbers 10 and 11, in which a ratio (T2/T1) of an average thickness (T2) of a Sn plating layer to an average thickness (T1) of a bonding layer including Au was 1 or less, it can be confirmed that adhesive strength was reduced.

In addition, for test number 1, in which a ratio (T2/T1) of an average thickness (T2) of a Sn plating layer to an average thickness (T1) of a bonding layer including Au was greater than 1000, it can be confirmed that a bonding misalignment evaluation result was NG.

Accordingly, as in an example embodiment of the present disclosure, when a ratio (T2/T1) of an average thickness (T2) of a Sn plating layer to an average thickness (T1) of a bonding layer including Au is greater than 1 and less than or equal to 1000, it can be confirmed that both a reduction in adhesive strength and bonding misalignment of the electronic component may be simultaneously alleviated.

While example embodiments have been shown and described above, it will be apparent to those skilled in the art that modifications and variations could be made without departing from the scope of the present disclosure as defined by the appended claims.

In addition, the term “an example embodiment” used herein does not refer to the same example embodiment, and is provided to emphasize a particular feature or characteristic different from that of another example embodiment. However, example embodiments provided herein are considered to be able to be implemented by being combined in whole or in part one with one another. For example, one element described in a particular example embodiment, even if it is not described in another example embodiment, may be understood as a description related to another example embodiment, unless an opposite or contradictory description is provided therein.

The terms used herein are for the purpose of describing particular example embodiments only and are to not be limiting of the example embodiments. As used herein, the singular forms “a,” “an,” and “the” are intended to include the plural forms as well, unless the context clearly indicates otherwise.

What is claimed is:

1. An electronic component comprising:
a capacitor including a body including a dielectric layer and an internal electrode, and an external electrode disposed on the body;
a connection terminal disposed on the external electrode; and
a bonding layer disposed between the capacitor and the connection terminal, the bonding layer including Au,
wherein the external electrode includes an electrode layer connected to the internal electrode, a Ni plating layer disposed on the electrode layer, and a Sn plating layer disposed on the Ni plating layer, and
when an average thickness of the bonding layer is defined as T1 and an average thickness of the Sn plating layer is defined as T2, T2>T1 is satisfied.

2. The electronic component of claim 1, wherein T2/T1 is greater than 1 and less than or equal to 1000.

3. The electronic component of claim 1, wherein Au included in the bonding layer is present in a form of an intermetallic compound including Au and Sn.

4. The electronic component of claim 1, wherein Au included in the bonding layer is present in a form of one or more selected from the group consisting of AuSn, AusSn, AuSn₂, and AuSn₄.

5. The electronic component of claim 1, wherein the bonding layer is free of glass.

6. The electronic component of claim 1, wherein the connection terminal is disposed on one of a first surface and a second surface of the external electrode.

7. The electronic component of claim 1, wherein the connection terminal is disposed on a first surface and a second surface of the external electrode.

8. The electronic component of claim 1, wherein
the external electrode includes a first external electrode and a second external electrode spaced apart from each other in a second direction, and
the connection terminal is disposed between both ends of the external electrode that oppose each other in the second direction.

9. The electronic component of claim 1, wherein
the external electrode includes a first external electrode and a second external electrode spaced apart from each other in a second direction, and
the connection terminal includes a concave groove extending inwardly from an end of the concave groove in the second direction.

10. The electronic component of claim 9, wherein
when the internal electrode and the dielectric layer are stacked in a first direction, and a direction, perpendicular to the first and second directions, is defined as a third direction, a length in the second direction of the connection terminal decreases toward a central portion in the third direction of the connection terminal.

11. The electronic component of claim 1, wherein the electronic component further includes a connection electrode portion connecting the external electrode and the connection terminal to each other.

12. The electronic component of claim 11, wherein the connection electrode portion covers an outermost surface of the external electrode and an outermost surface of the connection terminal.

13. The electronic component of claim 11, wherein the connection electrode portion includes a Ni plating portion covering an outermost surface of the external electrode and an outermost surface of the connection terminal, and a Sn plating portion disposed on the Ni plating portion.

14. The electronic component of claim 1, wherein the connection terminal includes a terminal body including Cu, and a terminal layer disposed on the terminal body, the terminal layer including Ni.

15. The electronic component of claim 14, wherein the Sn plating layer, the bonding layer, and the terminal layer are sequentially arranged.

16. A board comprising:
a substrate;
an electrode pad disposed on the substrate; and
the electronic component of claim 1 disposed on the electrode pad.
